(19) United States
(12) Patent Application Publication
(10) Pub. No.: US 2019/0281199 A1
(43) Pub. Date: Sep. 12, 2019

(54) Camera and Method of Detecting Image Data

(71) Applicant: SICK AG, Waldkirch (DE)

(72) Inventors: Romain MÜLLER, Waldkirch (DE); Florian SCHNEIDER, Waldkirch (DE)

(21) Appl. No.: 16/295,540

(22) Filed: Mar. 7, 2019

(30) Foreign Application Priority Data
Mar. 8, 2018 (DE) 102018105301.0

(51) Int. Cl. H04N 5/225; H01L 25/16; G06K 9/32; H04N 5/232; G01S 17/08

(52) U.S. Cl. CPC H04N 5/2256; H01L 25/167; G01S 17/08; H04N 5/232; G06K 9/3233

(57) ABSTRACT

A camera is provided comprising an image sensor for detecting image data from a detection zone; an optoelectronic distance sensor in accordance with the principle of a time of flight process; and a control and evaluation unit connected to the image sensor and to the distance sensor. The distance sensor has a plurality of light reception elements to generate a height profile and the control and evaluation unit is configured to use the height profile to determine camera parameters and/or to evaluate the image data.

The invention relates to a camera comprising an image sensor for detecting image data from a detection zone; an optoelectronic distance sensor in accordance with the principle of a time of flight process; and a control and evaluation unit connected to the image sensor and to the distance sensor. The invention further relates to a method of detecting image data from a detection zone in which a distance is measured using an additional optoelectronic distance sensor in accordance with the principle of a time of flight process.

Cameras are used in a variety of ways in industrial applications to automatically detect object properties, for example for the inspection or for the measurement of objects. In this respect, images of the object are recorded and are evaluated in accordance with the task by image processing methods. A further use of cameras is the reading of codes. Objects with the codes located thereon are recorded with the aid of an image sensor and the code regions are identified in the images and then decoded. Camera-based code readers also cope without problem with different code types than one-dimensional barcodes which also have a two-dimensional structure like a matrix code and provide more information. The automatic detection of the text of printed addresses, (optical character recognition, OCR) or of handwriting is also a reading of codes in principle. Typical areas of use of code readers are supermarket cash registers, automatic parcel identification, sorting of mail shipments, baggage handling at airports, and other logistic applications.

A frequent detection situation is the installation of the camera above a conveyor belt. The camera records images during the relative movement of the object stream on the conveyor belt and instigates further processing steps in dependence on the object properties acquired. Such processing steps comprise, for example, the further processing adapted to the specific object at a machine which acts on the conveyed objects or a change to the object stream in that specific objects are expelled from the object stream within the framework of a quality control or the object stream is sorted into a plurality of partial object streams. If the camera is a camera-based code reader, the objects are identified with reference to the affixed codes for a correct sorting or for similar processing steps.

The camera is frequently a part of a complex sensor system. It is, for example, customary with reading tunnels at conveyor belts to measure the geometry of the conveyed objects in advance using a separate laser scanner and to determine focus information, trigger times, image zones with objects and the like from it. The system only becomes intelligent and is able to reliably classify the information and to increase the information density by such a sensor network and a corresponding control.

Considered as an isolated sensor, conventional cameras are therefore only equipped with low intelligence or no intelligence of their own. It is also known to integrate a distance sensor in a camera, said distance sensor measuring the distance from an object to be recorded to set the focal position of an objective of the camera to it or to trigger an image recording if an object is at a specific distance. The distance sensor uses a time of flight (TOF) method for this, for example. This simple distance sensor is, however, only able to measure a single distance value at the front relative to the camera. The additional functionality that can be acquired by the distance sensor is thus very negligible.

It is therefore the object of the invention to improve the independent control or evaluation of a camera.

This object is satisfied by a camera and by a method of detecting image data from a detection zone in accordance with the respective independent claim. The camera records image data from the detection zone using an image sensor. The camera comprises, in addition to the image sensor, an optoelectronic distance sensor in accordance with the principle of the time of flight method. A control and evaluation unit has access to the image data of the image sensor and to the distance sensor.

The invention starts from the basic idea of using a spatially resolved distance sensor. A height profile is thereby available from a plurality of distance measurements using a plurality of light reception elements. The control and evaluation unit uses the height profile for the determination or setting of camera parameters, as a support in the evaluation of the image data, or also to trigger different functions of the camera.

The invention has the advantage that the distance sensor provides the requirement for increased inherent intelligence with its spatial resolution or multi-zone evaluation. The camera can thereby take decisions itself in its respective application to increase its performance or to improve the quality of the image data.

It is in particular possible here to decide autonomously whether information on the specific recording information should be collected at all and whether to reduce this information to the essential. This particularly profitably reduces the demands on bandwidth, memory requirements, and processing power, in particular when the camera is integrated in a large system (cloud, big data).

The control and evaluation unit is preferably configured to trigger a recording of the image sensor at a specific height profile. A comparison or a correlation is made for this purpose with a reference profile or with specific reference characteristics, for instance a middle height, the height of at least one central point within the height profiles, or the like, with a certain tolerance remaining allowed. Depending on the complexity of the specifications, it is thus possible to trigger the camera by objects in certain partial detection zones and at certain distances, but an at least rudimentary object recognition can also be implemented that, for example, ignores known objects.

The control and evaluation unit is preferably configured to decide on the basis of information on a reference profile of a container and of the height profile whether an empty container or a container with an object is located in the detection zone and to trigger a recording of the image sensor or not in dependence thereon. The reference profile as a whole or characteristics thereof describes/describe the empty container or, selectively, also the container with an object to be recorded. A distinction between empty and filled containers is now possible by the height profile recorded by the distance sensor and it is possible to directly only record the containers with objects. This can be understood as a special case of a triggering by a specific height profile, with said specific height profile being predefined by the empty container.

The control and evaluation unit is preferably configured to set a focal position of a reception optics of the image sensor in dependence on the height profile. Due to the spatial resolution, not only a general focus setting for a single frontally measured distance is possible here, but also an optimum setting for all the detected object points. Alternatively, a region of interest can be fixed for which a suitable distance value is provided due to the spatial resolution, with focusing then taking place suitably with said suitable distance value.

The control and evaluation unit is preferably configured to determine the inclination of a surface in the detection zone from the height profile. The surface is, for example, a base surface such as a floor or the plane of a conveyor. The detected inclination then serves for a calibration, for example. It is, however, equally conceivable to determine the inclination of at least one detected object surface.

This is a measurement parameter that is already of interest per se and that can additionally, for example, be used to perspectively rectify image data.

The control and evaluation unit is preferably configured to determine and/or to monitor the camera's own perspective using the height profile. The perspective comprises up to six degrees of freedom of space and of orientation, with the determination of only some of them already being advantageous, particularly since the respective application and installation frequently already determine degrees of freedom. The determination of the camera's own perspective is useful for its calibration. It is revealed by means of monitoring if the camera has been moved or impacted to warn or to automatically recalibrate. For this purpose, a reference profile of a desired position is predefined or is recorded in the initial aligned installation position and is compared therewith in operation. Averaging processes or other filters are sensible in order not to draw the incorrect conclusion of a camera movement from object movements in the detection zone.

The control and evaluation unit is preferably configured to determine regions of interest using the height profile. The height profile can represent properties of objects that are to be recorded. A reference profile of a background without objects of interest is particularly preferably predefined, either by initial teaching using the distance sensor or by a simple specification such as the assumption of a planar background. A conclusion is drawn on an object where the height profile deviates from the reference profile in operation and a corresponding region of interest is determined. Regions of interest can be output as additional information or the image data are already cropped in the camera and thus restricted to regions of interest.

The field of view of the distance sensor is preferably at least partially outside the detection zone. This at least relates to a lateral direction, preferably to all the relevant lateral directions. Advance information can be acquired in this manner before an object moves into the detection zone. A particularly preferred embodiment provides a field of view that is not next to the detection zone, but is rather larger and includes the detection zone.

The camera is preferably installed in a stationary manner at a conveying device that leads objects to be detected in a conveying direction through the detection zone. This is a very frequent industrial application of a camera. In addition, the underlying conditions are favorable for the simple, reliable acquisition of additional information from a height profile. There is a known, typically flat surface at a fixed distance in the form of a conveyor belt, or at least of trays or containers, and a uniform object stream effectively in only one dimension.

The control and evaluation unit is preferably configured to determine the speed of objects in the detection zone with reference to the height profile. The speed generally comprises the magnitude and/or the direction; both components can be of interest singly or together. A simple determination of direction is possible in that the location at which an object appears for the first time is detected in the height profile. This appearing object edge can also be tracked over a plurality of detections of the height profile to determine a speed by magnitude and direction.

The at least double detection of a height profile at different times with a subsequent correlation of object regions to estimate the displacement factor of the object and the speed vector together with the time difference of the detections is somewhat more complex, but more reliable. The effort of the evaluation at a conveying device is reduced because only the forward and backward directions have to be distinguished and all the objects are conveyed with the same magnitude of speed. Only the margin therefore has to be monitored for appearing objects in the direction of conveying and the direction in which these objects have then moved in further detections of the height profile is clear.

The camera preferably has an illumination unit for illuminating the detection zone, with the control and evaluation unit being configured to set the illumination unit using the height profile. An ideal lighting of the objects of interest can thereby be provided that avoids underexposure and overexposure and that compensates the quadratic intensity reduction as the distance increases.

The control and evaluation unit is preferably configured to identify code regions in the image data and to read their code content. The camera thus becomes a camera-based code reader for barcodes and/or 2D codes according to various standards, optionally also for text recognition (optical character recognition, OCR).

The method in accordance with the invention can be further developed in a similar manner and shows similar advantages in so doing. Such advantageous features are described in an exemplary, but not exclusive manner in the subordinate claims dependent on the independent claims.

The invention will be explained in more detail in the following also with respect to further features and advantages by way of example with reference to embodiments and to the enclosed drawing. The Figures of the drawing show in:

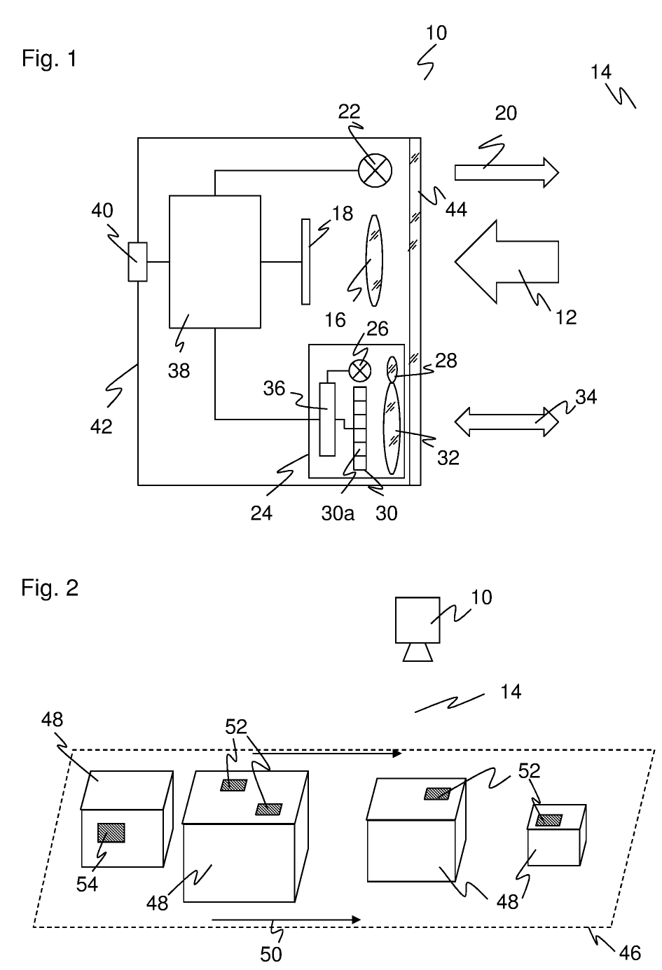

FIG. 1 a schematic sectional representation of a camera with a spatially resolved optoelectronic distance sensor;

FIG. 2 a three-dimensional view of an exemplary use of the camera in an installation at a conveyor belt;

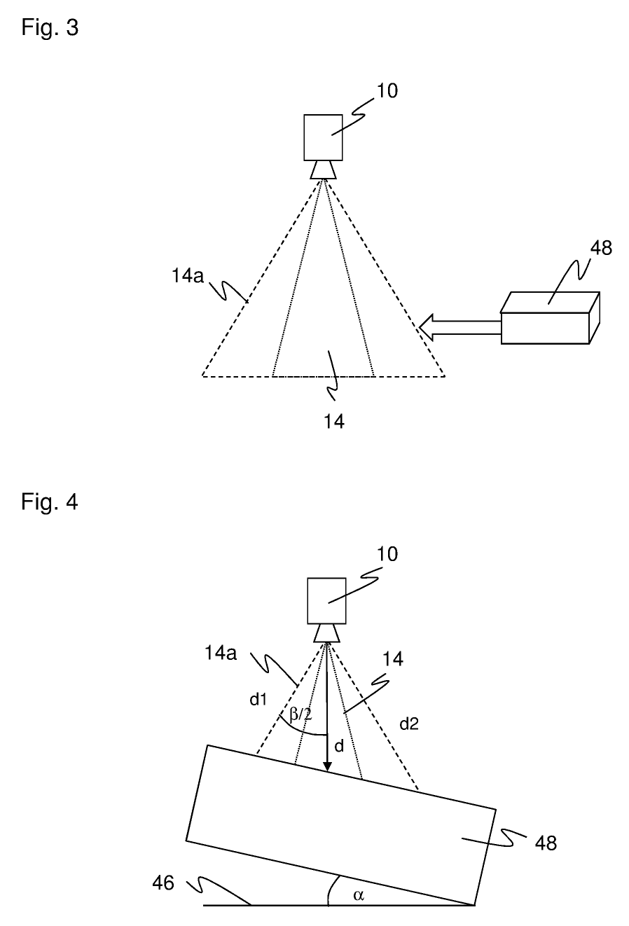

FIG. 3 a schematic representation of a camera and of its field of vision to explain the direction of movement of an object;

FIG. 4 a schematic representation of a camera and of its field of vision to explain the angular position of a detected surface;

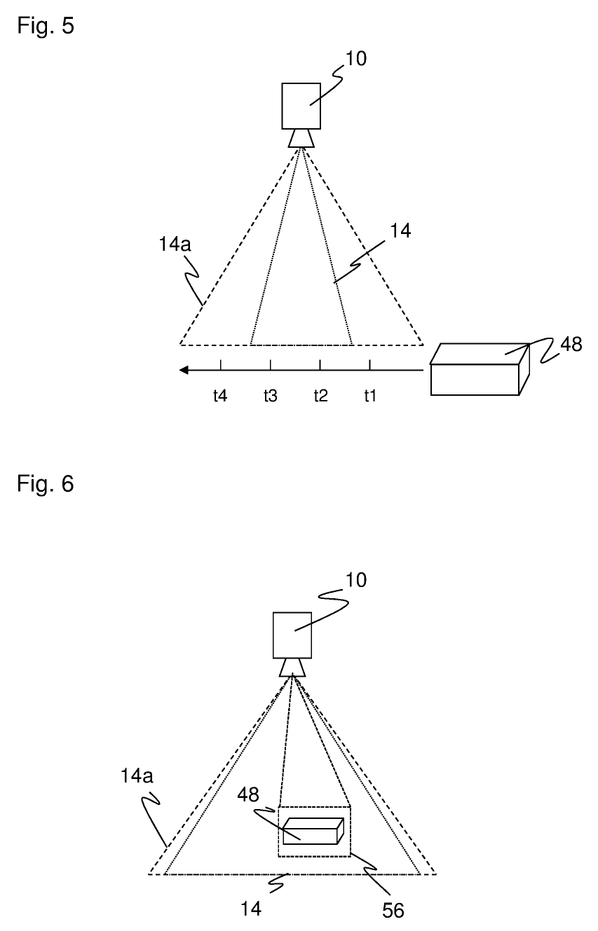

FIG. 5 a schematic representation of a camera and of its field of vision to explain the determining of the speed of an object;

FIG. 6 a schematic representation of a camera and of its field of vision to explain the determining of a region of interest with an object; and

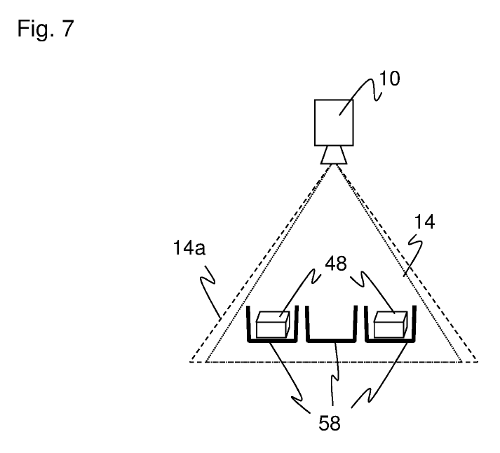

FIG. 7 a schematic representation of a camera and of its field of vision to explain the determining of a container with or without an object.

FIG. 1 shows a schematic sectional representation of a camera 10. Received light 12 from a detection zone 14 is incident on a reception optics 16 that conducts the received light 12 to an image sensor 18. The optical elements of the reception optics 16 are preferably configured as an objective composed of a plurality of lenses and other optical elements such as diaphragms, prisms, and the like, but here only represented by a lens for reasons of simplicity.

To light the detection zone 14 with transmitted light 20 during a recording of the camera 10, the camera 10 comprises an optional illumination unit 22 that is shown in FIG. 1 in the form of a simple light source and without a transmission optics. In other embodiments, a plurality of light sources such as LEDs or laser diodes are arranged around the reception path, in ring form, for example, and can also be multi-color and controllable in groups or individually to adapt parameters of the illumination unit 22 such as its color, intensity, and direction.

In addition to the actual image sensor 18 for detecting image data, the camera 10 has an optoelectronic distance sensor 24 that measures distances from objects in the detection zone 14 using a time of flight (TOF) process. The distance sensor 24 comprises a TOF light transmitter 26 having a TOF transmission optics 28 and a TOF light receiver 30 having a TOF reception optics 32. A TOF light signal 34 is thus transmitted and received again. A time of flight measurement unit 36 determines the time of flight of the TOF light signal 34 and determines from this the distance from an object at which the TOF light signal 34 was reflected back.

The TOF light receiver 30 has a plurality of light reception elements 30a or pixels and is thus spatially resolved. It is therefore not a single distance value that is detected, but rather a spatially resolved height profile (depth map, 3D image). Only a relative small number of light reception elements 30a and thus a lateral resolution of the height profile is provided in this process. 2×2 pixels or even only 1×2 pixels can already be sufficient. A more highly laterally resolved height profile having n×m pixels, n, m>2, naturally allows more complex and more accurate evaluations. The number of pixels of the TOF light receiver 30, however, remains comparatively small with, for example, some tens, hundreds, or thousands of pixels or n, m≤10, n, m≤20, n, m≤50, or n, m≤100, far removed from typical megapixel resolutions of the image sensor 18.

The design of the distance sensor 24 is purely exemplary. In the further description of the invention with reference to FIGS. 3 to 7, the distance sensor 24 is treated as an encapsulated module that provides a height profile on request. The optoelectronic distance measurement by means of time light processes is known and will therefore not be explained in detail. Two exemplary measurement processes are photomixing detection using a periodically modulated TOF light signal 34 and pulse time of flight measurement using a pulse modulated TOF light signal 34. There are also highly integrated solutions here in which the TOF light receiver 30 is accommodated on a common chip with the time of flight measurement unit 36 or at least parts thereof, for instance TDCs (time to digital converters) for time of flight measurements. In particular a TOF light receiver 30 is suitable for this purpose that is designed as a matrix of SPAD (single photon avalanche diode) light reception elements. The TOF optics 28, 32 are shown only symbolically as respective individual lenses representative of any desired optics such as a microlens field.

A control and evaluation unit 38 is connected to the illumination unit 22, to the image sensor 18, and to the distance sensor 38 and is responsible for the control work, the evaluation work, and for other coordination work in the camera 10. It therefore reads image data of the image sensor 18 to store them and to output them at an interface 40. The control and evaluation unit 38 uses the height profile of the distance sensor 24 in dependence on the embodiment for different purposes, for instance to determine or set camera parameters, to trigger camera functions, or to evaluate image data, which also includes pre-processing work for an actual evaluation in the camera 10 or in a higher ranking system. The control and evaluation unit 38 is preferably able to localize and decode code regions in the image data so that the camera 10 becomes a camera-based code reader.

The camera 10 is protected by a housing 42 that is terminated by a front screen 44 in the front region where the received light 12 is incident.

FIG. 2 shows a possible use of the camera 10 in an installation at a conveyor belt 46. The camera 10 is shown here and in the following only as a symbol and no longer with its structure already explained with reference to FIG. 1. The conveyor belt 46 conveys objects 48, as indicated by the arrow 50, through the detection zone 14 of the camera 10. The objects 48 can bear code regions 52 at their outer surfaces. It is the object of the camera 10 to detect properties of the objects 48 and, in a preferred use as a code reader, to recognize the code regions 52, to read and decode the codes affixed there, and to associate them with the respective associated object 48. In order also to recognize object sides, in particular laterally applied code regions 54, additional cameras 10, not shown, are preferably used from different perspectives.

Different possibilities of utilizing the height profile or the multi-zone evaluation of the distance sensor 24 to equip the camera 10 with a certain intelligence of its own will now be explained with reference to FIGS. 3 to 7. The division into individual Figures only serves for clarity; the different functions can be combined as desired.

One application possibility is the regulation of a focus adjustment. Unlike a conventional autofocus using a simple distance sensor, the height profile allows a direct focusing on any desired details or the selection of a focal position at which as many relevant object points as possible are disposed in the depth of field zone. The same applies accordingly to the triggering of the camera 10 if an object is located within a matching distance region. Whether an object is actually of interest can also be decided with substantially more selectivity here due to the height profile.

FIG. 3 shows a camera 10 above an object 48 moving laterally into the detection zone 14 of said camera 10. In this respect, a distinction must still be made between the detection zone 14 of the image sensor 18 and the field of vision 14a of the distance sensor 24. Both preferably considerably overlap and it is particularly advantageous if the distance sensor has a larger field of view than the camera 10 and is thereby larger, at least at one side, even more preferably in all the lateral directions of the field of vision 14a, than the detection zone 14 and includes it. At least an outer margin of the height profile is then namely already available in advance of the actual recording by the image sensor 18.

The object 48 now comes from a specific direction, from the right in this case. This is recognized by the height profile because the distance sensor 24 at the right margin of its field of vision 14a measures a shorter distance on the entry of the object 48 than before. The camera 10 can now be prepared, for instance a focal position or a trigger time can be set.

This direction recognition is particularly advantageous if the object 48 is disposed on a conveyor belt 46, as in FIG. 2. A distinction can then be made whether the conveyor belt 46 runs forward or backward and a specific mode can accordingly be selected; for example, with a backward running belt, the last measurement can be deleted because the object 48 will be included again.

FIG. 4 shows a camera 10 above a slanted surface of an object 48. The angle of inclination a of the surface can be determined form the height profile with respect to a reference such as the floor or the conveyor belt 46. Trigonometric calculations or the specification of certain height profiles characteristic for a respective angle of inclination are conceivable for this purpose. FIG. 4 illustrates by way of example the field of view β of the field of vision 14a, the shortest distance d, and two distances d1 and d2 at the margins as possible parameters for a trigonometric measurement of α. The angle of inclination a can be used, for example, to rectify from a perspective aspect, that is to generate an image from the image data that corresponds to a perpendicular orientation.

Alternatively, it is not the angle of inclination a of a surface of an object 48 that is determined, but rather of a reference surface. In other words, the alignment of the camera 10 itself is measured here, for example with respect to the floor or to the conveyor belt 46. This can be useful as an adjustment aid or for an initial calibration of the camera 10. The camera 10 can moreover determine in operation whether the initial angle of inclination a is maintained. A change is understood as an unwanted loss of the calibration of the camera 10 by impact or the like and, for example, a warning is output or an independent recalibration is also carried out. An only transient change, that is one caused by objects 48, should be excluded here by a longer observation time period, by averaging, or by other suitable measures.

Such a calibration aid and self-monitoring also do not have to be based on one surface and on a single angle of inclination a. Alternatively, a height profile having any desired static articles as a reference is used. The camera 10 is then also able to recognize a permanent change and thus to recognize a no longer present own position and/or orientation.

FIG. 5 shows a camera 10 above a laterally moved object 48 to explain a speed determination. Its position is determined multiple times for this purpose, here by way of example at four points in time t1 . . . t4. The speed can be calculated as the positional change per time while taking account of the respective time elapsed between two position determinations and the measured distance from the object 48 or an assumed distance approximately corresponding to an installation height of the camera 10. In an application at a conveyor belt 46, the evaluation is simplified because the direction of movement is known. Alternatively, the direction is determined as required in the camera 10 as explained with reference to FIG. 2. It is also conceivable by a detection of the magnitude and direction of the speed to notice atypical movements and to draw attention to a possible hazardous situation.

FIG. 6 shows a camera 10 above an object 48 that only takes up a relatively small partial region of the detection zone 14. The position of the object 48 and thus a region of interest 56 can be detected with the aid of the height profile. The camera 10 can use this information itself to crop the image to the region of interest 56 or only to look for codes there and thus to work more efficiently and faster. A further possibility is to leave the image data as they are, but to also output the information on the region of interest 56. However, the cropping has the advantage that fewer data are generated overall.

FIG. 7 shows a camera 10 above a plurality of containers 58 in some of which an object 48 is located. The containers 58 are in the detection zone 14 simultaneously or after one another depending on the situation and application. Application examples include a tray conveyor or a conveyor belt 46 on which objects 48 are conveyed in boxes. The camera 10 recognizes whether the respective container 58 is carrying an object 48 or not using reference profiles of an empty container 58 or its characteristic properties; for instance, a high marginal region with a lower surface therebetween. The camera 10 then, for example, triggers a recording only for a filled container 58 or it only places regions of interest 56 around filled containers. An unnecessary data acquisition for empty containers 58 is omitted.

The containers 58 are an example for a specific known environment that is recognized from the height profile and in which an object 48 is to be detected. The camera 10 can generally recognize from the height profile whether and where objects 48 are located that should no longer be interpreted as background in order to directly restrict recordings to relevant situations.

A further application possibility of the height profile is the adaptation of the illumination unit 22. The illumination intensity decreases quadratically with the distance. To nevertheless ensure an optimum contrast and to avoid saturation, the illumination can, for example, be optimized or readjusted by the current of the illumination unit 22, by a diaphragm, or by the exposure time of the image sensor 18 in dependence on the height profile. It is also conceivable within the framework of such adaptations to activate or deactivate different illumination modules or groups of light sources. Not only a larger interval of possible intensities can thus be covered, but the illumination can also even be locally adapted to the height profile. The intensity and the distribution of extraneous light can furthermore also be determined and the illumination can also be adapted thereto, which in particular further improves the image data in external applications.

The use of a spatially resolved distance sensor 24 and the internal utilization of its height profile for more intelligence of the camera 10 can also be transferred to other sensors, for example, to light barriers, laser scanners, and even to non-optical sensors.

1. A camera comprising:
an image sensor for detecting image data from a detection zone;
an optoelectronic distance sensor in accordance with the principle of a time of flight process; and
a control and evaluation unit connected to the image sensor and to the distance sensor,
wherein the distance sensor has a plurality of light transmission elements to generate a height profile; and wherein the control and evaluation unit is configured to utilize the height profile to determine camera parameters and/or to evaluate the image data.

2. The camera in accordance with claim 1,
wherein the control and evaluation unit is configured to trigger a recording of the image sensor at a specific height profile.

3. The camera in accordance with claim 1,
wherein the control and evaluation unit is configured to decide on the basis of information on a reference profile of a container and of the height profile whether an empty container or a container with an object is located in the detection zone and to trigger a recording of the image sensor or not in dependence thereon.

4. The camera in accordance with claim 1,
wherein the control and evaluation unit is configured to set a focal position of a reception optics of the image sensor in dependence on the height profile.

5. The camera in accordance with claim 1,
wherein the control and evaluation unit is configured to determine the inclination from the height profile.

6. The camera in accordance with claim 1,
wherein the control and evaluation unit is configured to determine the camera's own perspective with reference to the height profile.

7. The camera in accordance with claim 1,
wherein the control and evaluation unit is configured to monitor the camera's own perspective with reference to the height profile.

8. The camera in accordance with claim 1,
wherein the control and evaluation unit is configured to determine and to monitor the camera's own perspective with reference to the height profile.

9. The camera in accordance with claim 1,
wherein the control and evaluation unit is configured to fix regions of interest with reference to the height profile.

10. The camera in accordance with claim 1,
wherein the control and evaluation unit is configured to fix regions of interest with reference to the height profile while taking a reference profile into account.

11. The camera in accordance with claim 1,
wherein the field of vision of the distance sensor is at least partly disposed outside the detection zone.

12. The camera in accordance with claim 1,
that is installed in a stationary manner at a conveying device that guides objects to be detected in a direction of conveying through the detection zone.

13. The camera in accordance with claim 1,
wherein the control and evaluation unit is configured to determine the speed of objects in the detection zone with reference to the height profile.

14. The camera in accordance with claim 1,
that has an illumination unit for illuminating the detection zone; and wherein the control and evaluation unit is configured to set the illumination unit with reference to the height profile.

15. The camera in accordance with claim 1,
that has a control and evaluation unit that is configured to identify code regions in the image data and to read their code content.

16. A method of detecting image data from a detection zone in which a distance is measured using an additional optoelectronic distance sensor in accordance with the principle of a time of flight process,
wherein a spatially resolved height profile is generated by the distance sensor and the height profile is utilized to determine recording parameters of the detection of the image data and/or to evaluate the image data.
